(19) United States
(12) Patent Application Publication
(10) Pub. No.: US 2005/0104525 A1
(43) Pub. Date: May 19, 2005

(54) Reducing apparatus and method

(75) Inventor: Takayuki Komiya, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/986,386

(22) Filed: Nov. 12, 2004

(30) Foreign Application Priority Data
Nov. 19, 2003 (JP) 2003-389809

(51) Int. Cl. H01J 7/24; H05B 31/26; H01L 21/20; H01L 21/469

(52) U.S. Cl. 315/111.01; 438/778

(57) ABSTRACT

A reduction process is performed at a low temperature to thereby realize a high production yield. An ion supply unit heats negative ions containing hydride ions to a predetermined temperature. The ion supply unit applies an electric field to a negative ion source with a predetermined intensity, so that the hydride ions are extracted from the negative ion source. Further, the ion supply unit supplies the hydride ions extracted into a processing chamber by a nonreactive gas of a carrier gas to thereby reduce an oxide film formed on a surface of a metallic film on a semiconductor wafer disposed inside the processing chamber.

### FIELD OF THE INVENTION

The present invention relates to a method and apparatus for reducing an oxide film on a surface of a metallic film.

### BACKGROUND OF THE INVENTION

For realizing a rapid operating speed of a semiconductor apparatus, a copper may be employed to a wiring and the like.

Since the copper tends to be easily oxidized, there may be adopted a removing step of an oxide film formed on a surface of a copper film forming the wiring and the like, in a fabrication of the semiconductor apparatus.

Conventionally, in order to remove the oxide film from the surface of the copper film, a hydrogen gas containing a small amount of oxygen gas (for example, see reference 1), or a formic acid (carboxylic acid) (for example, see reference 2) has been used.

In a method using the above-described hydrogen gas, the oxide film on the surface of the copper film is removed by making an inside of a processing chamber into a hydrogen atmosphere and heating a substrate on which the copper film is formed at 400° C. for one minute.

Further, in a method using the above-described formic acid, the oxide film on the surface of the copper film is removed by introducing the formic acid into the processing chamber, and then, heating the substrate on which the copper film is formed at 200˜350° C. for about six minutes.
[reference 1] Japanese Patent Laid-Open Application No. 2002-217199 (paragraph 0025)
[reference 2] Japanese Patent Laid-Open Application No. 2002-270609 (paragraphs 0078 and 0084)

As shown in FIG. 7, for example, a copper wiring 104 may be buried in a wiring trench 103 formed in an interlayer insulating film 102 on a semiconductor substrate 101 (a semiconductor wafer) by way of, e.g., a damascene method.

The interlayer insulating film 102 may be made of a low-k film, and the film quality of the low-k film may be deteriorated at a temperature higher than 200° C.

If the deteriorated low-k film is employed as the interlayer insulating film, the film quality of the low-k film (interlayer insulating film and the like) may be deteriorated when the aforementioned methods using the hydrogen gas and the formic acid are applied.

If the film quality of the interlayer insulating film is deteriorated, a characteristic of a finished semiconductor apparatus may be declined, resulting in poor production yield.

### SUMMARY OF THE INVENTION

It is, therefore, a primary object of the present invention to provide a reducing apparatus and a reducing method capable of realizing a high production yield.

Further, another object of the present invention is to provide a reducing apparatus and a reducing method capable of performing a reduction process at a low temperature.

In accordance with one aspect of the invention, there is provided a reducing apparatus for reducing an oxide film formed on a surface of a metallic film formed on a semiconductor wafer, wherein the oxide film is reduced by using hydride ions.

In accordance with the present invention, the oxide film is reduced. Since the hydride ions have high reactivity, the temperature of the semiconductor wafer can be set at a low temperature, e.g., at which film quality of an interlayer insulating film and the like can be maintained. Namely, even though the interlayer insulating film and the like are formed on the semiconductor wafer, deterioration of the film quality of the interlayer insulating film and the like can be prevented. As a result, a high production yield can be realized.

The reducing apparatus may include an ion generation unit for producing the hydride ions, and an ion supply unit for supplying the hydride ions produced by the ion generation unit onto the semiconductor wafer.

The ion generation unit may have a source heating unit for heating a negative ion source containing the hydride ions, and an electric field applying unit for applying an electric field to the negative ion source heated by the source heating unit to extract the hydride ions contained in the negative ion source.

It is preferable that the electric field applying unit may apply to the negative ion source an electric field in the range from 200 to 2000 V/cm.

More preferably, the electric field applying unit may apply to the negative ion source an electric field in the range from 400 to 1500 V/cm.

The source heating unit may heat the negative ion source to 250˜1000° C.

The heating temperature is preferably 400˜800° C., and more preferably, 700° C.

The reducing apparatus may further include a wafer heating unit for heating the semiconductor wafer, and the wafer heating unit may heat the semiconductor wafer to 30˜200° C.

The heating temperature of the semiconductor wafer is preferably 100˜180° C., and more preferably, 150° C.

By heating the semiconductor wafer to such a temperature, even in case where the interlayer insulating film and the like are formed on the semiconductor wafer, deterioration of the film quality of the interlayer insulating film and the like can be prevented. As a result, a high production yield can be realized.

Further, the reducing apparatus may include a processing chamber for performing a reduction process on the oxide film; and a pressure control unit for controlling an inner pressure of the processing chamber, wherein the inner pressure of the processing chamber is set at a near atmospheric pressure by the pressure control unit.

The metallic film may be formed of a copper, and the oxide film may be formed of cuprous oxide.

In accordance with another aspect of the present invention, there is provided a method for reducing an oxide film formed on a surface of a metallic film formed on a semiconductor wafer, wherein the oxide film being reduced by using hydride ions.

### BRIEF DESCRIPTION OF THE DRAWINGS

The above and other objects and features of the present invention will become apparent from the following description of preferred embodiments given in conjunction with the accompanying drawings, in which:

FIG. 1A shows a construction of an ion source generation unit in accordance with a preferred embodiment of the present invention, and FIG. 1B illustrates a cross sectional view taken along A-A′ line of FIG. 1A;

FIGS. 2A and 2B illustrate shapes of an object to be processed corresponding to a negative ion source S;

FIG. 3 is a block diagram for showing a reducing apparatus in accordance with a preferred embodiment of the present invention;

FIG. 4 shows a configuration of a contact electrode forming a reducing apparatus;

FIGS. 5A through 5C are views for showing other configurations of an ion supply unit;

FIG. 6 provides another configuration of a reducing apparatus; and

FIG. 7 sets forth to a view for showing a copper wiring formed on a substrate.

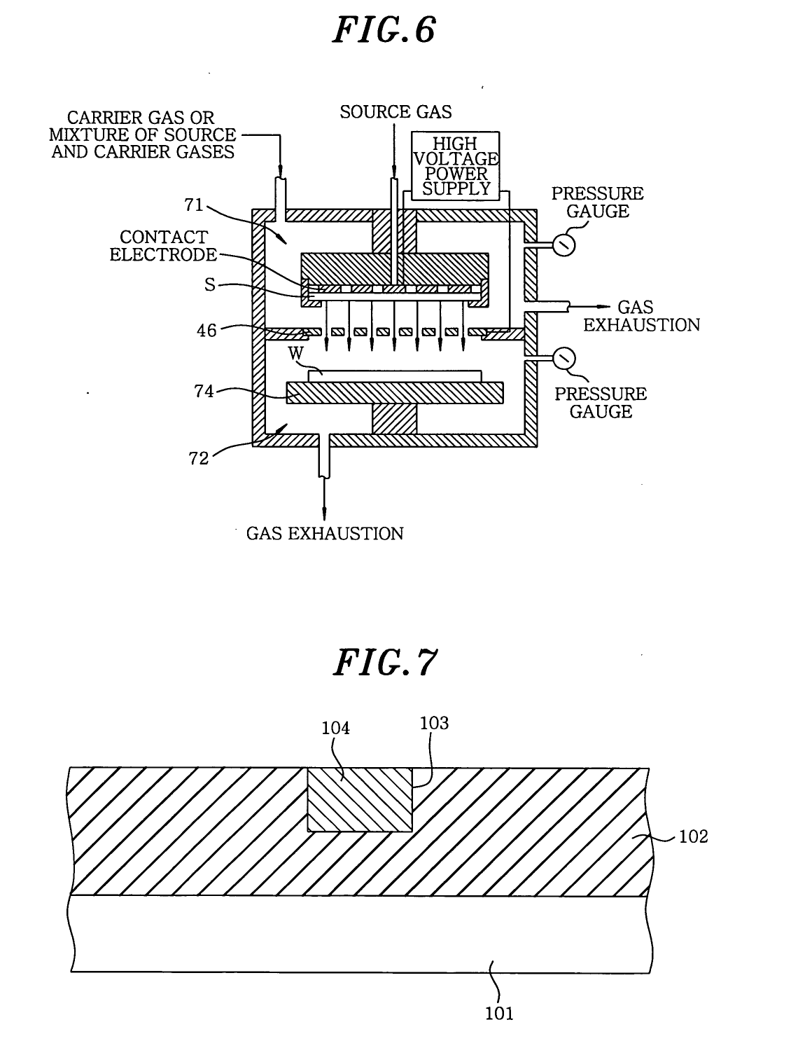

### DETAILED DESCRIPTION OF THE PREFERRED EMBODIMENTS

Hereinafter, preferred embodiments of the present invention will be described in detail with reference to the accompanying drawings.

In a reducing method in accordance with the preferred embodiment, by using negative ions, e.g., hydride ions (H⁻), and an oxide film on a surface of a metallic film formed on a semiconductor wafer (a semiconductor substrate), specifically, a cuprous oxide (Cu₂O) film on a surface of a copper film is removed by way of a reduction.

An ion source generation unit for producing a negative ion source which provides negative ions may be formed of an atmosphere controllable electric furnace used in, e.g., the ceramic industry.

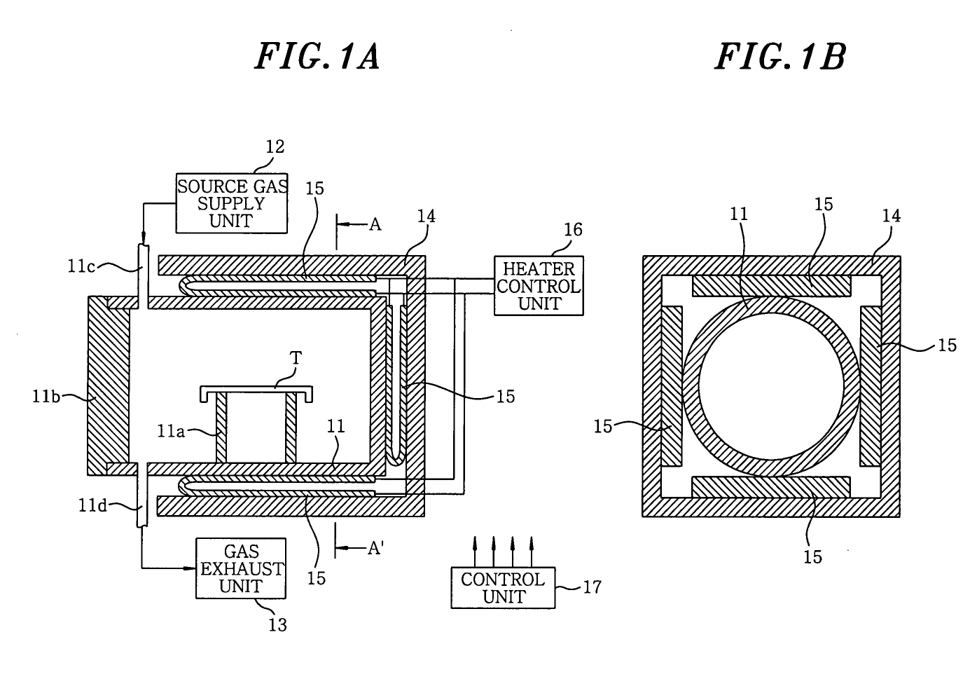

FIGS. 1A and 1B describe configurations of the ion source generation unit. Here, FIG. 1B is a cross sectional view of the ion source generation unit taken along A-A′ line of FIG. 1A.

As shown in FIG. 1A, the ion source generation unit includes a processing vessel 11, a source gas supply unit 12, a gas exhaustion unit 13, a thermal insulation vessel 14, a heater 15, a heater control unit 16 and a control unit 17.

The processing vessel 11 may be a heat resistant vessel made of a heat resistant metal or a highly reduction-resistant ceramic. For example, the processing vessel may be a cylindrical vessel made of highly pure alumina.

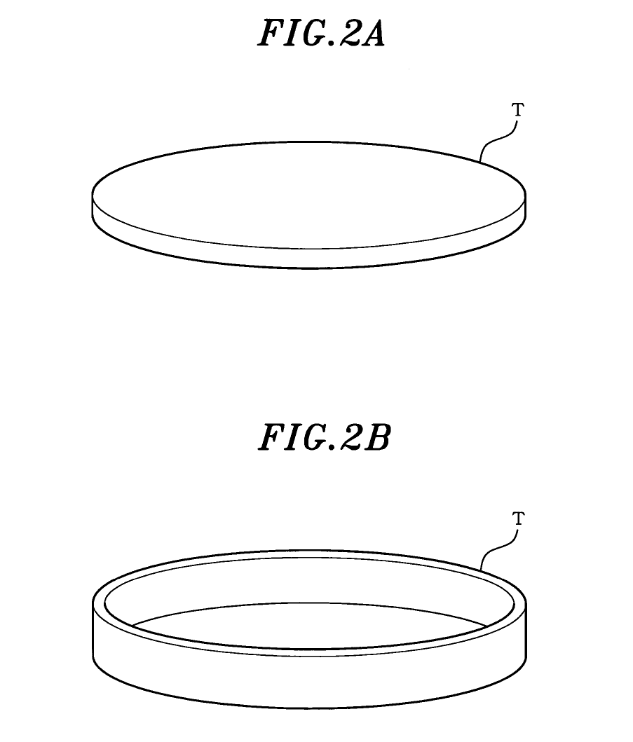

In the processing vessel 11, there is installed a mounting table 11a made of alumina for mounting thereon an object to be processed T corresponding to the negative ion source. The shape of the object to be processed T may be a schale shape shown in FIG. 2B as well as a disk shape shown in FIG. 2A. The object to be processed T is loaded and unloaded by opening a lid 11b of the processing vessel 11.

Further, in a wall of the processing vessel 11, there are installed a gas supply line 11c for supplying a source gas for producing the negative ion source and a gas exhaust line 11c for discharging a gas from the processing vessel 11.

The source gas supply unit 12 is connected to the processing vessel 11 via the gas supply line 11c, and supplies into the processing vessel 11 a source gas (a hydrogen containing gas) needed for generating the negative ion source.

The gas exhaust unit 13 having a gas exhaust pump and the like is connected to the processing vessel 11 via the gas exhaust line lid, and discharges a gas from the processing vessel 11.

The thermal insulation vessel 14 is formed of a thermal insulator, and a pipe shaped heater 15 is installed on an inner wall thereof. The processing vessel 11 is accommodated in the thermal insulation vessel 14 and heated by the heater 15.

The heater control unit 16 is connected to the heater 15 installed inside the thermal insulation vessel 14, release a predetermined amount of currents towards the heater 15 to thereby generate a heat, which raises the temperature of the inside of the processing vessel 11 accommodated in the thermal insulation vessel 14 to a predetermined point.

The control unit 17 is formed of a microcomputer and the like, and stores a program for producing the negative ion source. The control unit 17 controls entire operations of the ion source generation unit according to the program stored, to thereby generate the negative ion source.

For example, the control unit 17 controls the source gas supply unit 12 to supply the source gas into the processing vessel 11. Further, the control unit 17 controls the gas exhaust unit 13 to set an inner pressure of the pressing vessel 11 at a predetermined pressure. Still further, the control unit 17 controls the heater control unit 16 to heat the inside of the processing vessel 11 to a predetermined temperature.

Next, an operation of the ion source generation unit will be discussed.

The object to be processed T is mounted on the mounting table 11a, and the lid 11b is closed to make the inside of the processing vessel 11 airtight. The object to be processed T is made of, e.g., a 12CaO.7Al₂O₃ (C12A7).

If the object to be processed T is loaded in the processing vessel 11, the ion source generation unit performs an operation as explained below, in response to an instruction of, e.g., an operator. Meanwhile, the following operation is carried out under the control of the control unit 17.

First, the source gas supply unit 12 supplies a gaseous mixture of hydrogen 20% and nitrogen 80% as the source gas into the processing vessel 11.

Subsequently, the gas exhaust unit 13 discharges the gas from the processing vessel 11 to set the inner pressure of the processing vessel 11 at a predetermined pressure. Specifically, the inner pressure of the processing vessel 11 is set at an atmospheric pressure (e.g., 9×10⁴˜11×10⁴ Pa) by the gas exhaust unit 13.

Further, the heater control unit 16 flows a predetermined amount of currents towards the heater 15 to generate a heat from the heater 15, and heats the inside of the processing vessel 11 to a predetermined temperature (about 1300° C.).

This state is maintained for about two hours by the control unit 17. As a result, the object to be processed T becomes the negative ion source (hydrogen substituted C12A7) providing the negative ions (hydride ions; H⁻).

The negative ion source produced like above incorporates the negative ions (hydride ions; H⁻) into a cage formed by AlO₄ tetrahedra.

The negative ions inside the negative ion source are extracted by heating the negative ion source to a predetermined temperature and applying an electric field thereto with a predetermined intensity, as described below, to thereby reduce the surface of the metallic film.

Next, the reducing apparatus for performing the reduction of the surface of the metallic film will be discussed.

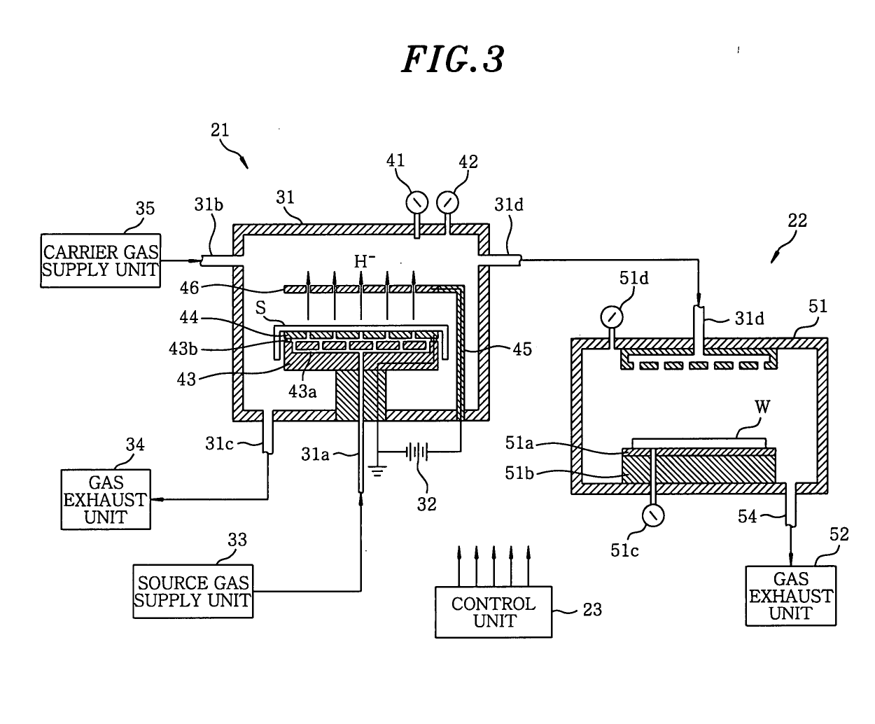

As shown in FIG. 3, the reducing apparatus includes an ion supply unit 21 for supplying the negative ions, a reduction unit 22 for performing a reduction process using the negative ions, and a control unit 23 for controlling the ion supply unit 21 and the reduction unit 22.

The ion supply unit 21 has a processing chamber 31, a high voltage power supply 32, a source gas supply unit 33, a gas exhaust unit 34 and a carrier gas supply unit 35, and extracts the negative ions from the negative ion source S and supplies them to the reduction unit 22.

The processing chamber 31 is made of, e.g., alumina and the like. On a wall of the processing chamber 31, there are installed lines for flowing various gases.

Specifically, there are installed a source gas supply line 31a for introducing a source gas into the processing chamber 31, a carrier gas supply line 31b for introducing a carrier gas into the processing chamber 31, a gas exhaust line 31c for discharging a gas from the processing chamber 31 and an ion supply line 31d for transferring extracted negative ions to the reduction unit 22 by the carrier gas.

Meanwhile, the carrier gas supply line 31b and the ion supply line 31d are installed facing each other such that the transfer of the negative ions by the carrier gas introduced into the processing chamber 31 is smoothly carried out.

Further, if the negative ions collide with the wall, or are bonded with other chemical species, the activation thereof becomes less. Thus, an inner diameter of the ion supply line 31d is set as large as possible and a length thereof is set as short as possible. Further, an inner wall of the ion supply line 31d is made of a fluorocarbon (particularly, PTFE; tetrafluoroethylene resin), Teflon (registered trademark), or the like, which is unlikely to react with the negative ions. Still further, the ion supply line 31d is grounded or maintained at a minus potential during the processing so as not to attract the negative ions.

Still further, a nonreactive gas may be used as the carrier gas to maintain an oxygen-reduced atmosphere from the ion generation to the processing chamber. Here, it is preferable that the nonreactive gas contains the source (hydrogen gas). By this, such an effect can be obtained that the activation of the negative ions is kept (recombination is reduced).

Still further, it is preferable that a region where the carrier gas is supplied (a region placed above an extraction electrode 46 that will be discussed later inside the processing chamber 31) is set as small as possible as long as the negative ions do not collide with the wall, so that a gas velocity of the carrier gas is maintained at a high speed.

Still further, on the wall of the processing chamber 31, there are equipped a temperature gauge 41 measuring a temperature inside the processing chamber 31 and a pressure gauge 42 measuring an inner pressure of the processing chamber 31.

The heater 43, the contact electrode 44, the electrode supporting member 45 and a hydride ion extraction electrode 46 are installed in the processing chamber 31.

The heater 43 is disposed in a substantially center of the processing chamber 31, and heats the negative ion source S placed inside the processing chamber 31 to a predetermined temperature that will be discussed later. Inside the heater 43, a source gas supply line 31a is connected and a gas channel 43a for emitting from the surface of the heater 43 the source gas introduced via the source gas supply line 31a is formed.

The contact electrode 44 is manufactured while being attached to the negative ion source S. The contact electrode 44 is porous and has voids through which the source gas can pass, and manufactured to have a triple phase boundary of the source gas, the negative ion source S and the contact electrode 44. As a method for manufacturing the contact electrode 44, for example, there is a method that, e.g. a fine powder is formed in a film shape and sintered, or a film is deposited by a sputtering or an evaporation.

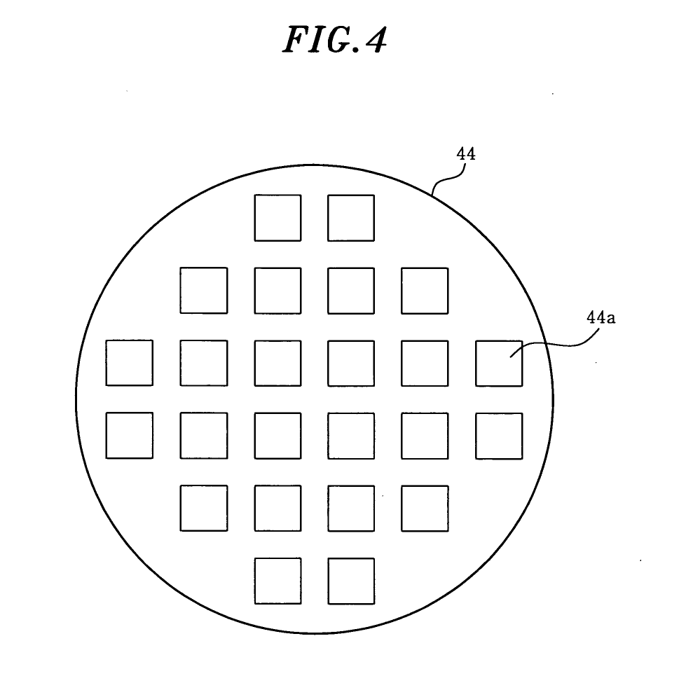

Further, for increasing a contact area with the source gas, the contact electrode 44 may be formed in a mesh shape, as shown in FIG. 4, to have a plurality of openings 44a. The contact electrode 44 is electrically connected to a negative pole of the high voltage power supply 32 for applying an electric field. In order to prevent a large amount of source gases from flowing through a space between the contact electrode 44 and the heater 43, the space is protected by protrusions 43b and airtightly maintained.

As a material for use in the contact electrode 44, there may be enumerated like below:
(1) a doped perovskite type (ABO₃) complex oxide having a proton conductivity;
(2) a hydride ion-containing material
(3) a ceria-based material
(4) a material having a high ion conductivity for a stable metal under a reduction atmosphere

As for the material of (1), there are enumerated, e.g., Sr(Ce, In)O₃: In doped strontium cerium oxide, In doped barium cerium oxide, Ca(Zr, In)O₃: In doped calcium zirconium oxide, LaAlO₃: lanthanum aluminum oxide, lanthanum aluminate, and the like.

As for the material of (2), there are enumerated MgO:H (obtained by reducing MgO (magnesia) in hydrogen), LaSrCoO₃H_{0.7} [hydrogen substituted topochemically treated (structure-maintained) lanthanum strontium cobalt oxide having a K_{2 NiF}₄ type structure (perovskite related structure)], and the like.

As for the material of (3), there are enumerated GDC (20 mol % GdO_{1.5}-CeO₂): Gadolinium doped ceria, SDC (20 mol % SmO_{1.5}-CeO₂): Samarium doped ceria, and the like.

As for the material of (4), there are enumerated Pt, Au, Ag, and the like. Further, other metals may be used as the contact electrode 44 in case of a relatively low processing temperature.

One end of the electrode supporting member 45 is fixed at the wall of the processing chamber 31. The extraction electrode 46 is supported by the electrode supporting member 45 to face the contact electrode 44. Further, the extraction electrode 46 is disposed below the carrier gas supply line 31b and the ion supply line 31d since the carrier gas for transferring the negative ions is supplied to the upper part inside the processing chamber 31.

The extraction electrode 46 refers to an electrode formed in a shape capable of passing therethrough the negative ions extracted from the negative ion source S. For example, the extraction electrode 46 may be made of a metallic electrode, a ceramic electrode, or a composite material thereof, which has a mesh shape. Further, e.g., a disk shape having a hole in the center thereof may be adopted. Still further, as a metal for the extraction electrode 46, there are Pt, Au, and the like having a reduction resistance (hydridization resistance).

The high voltage power supply 32 has a negative pole connected to the contact electrode 44 via a wiring passing through the heater 43, and a positive pole connected to the extraction electrode 46 via a wiring passing through the electrode supporting member 45. By applying a predetermined voltage between the contact electrode 44 and the extraction electrode 46, an electric filed is applied to the negative ion source S by the high voltage power supply 32 with an intensity that will be discussed later. As a result, the negative ions are extracted from the negative ion source S heated to a predetermined temperature.

The source gas supply unit 33 is connected to the processing chamber 31 via the source gas supply line 31a. The source gas supply unit 33 supplies into the processing chamber 31 via the source gas supply line 31a the source gas (the hydrogen gas or a gaseous mixture of the hydrogen gas and the nonreactive gas) for filling with new negative ions the negative ion source S, from which the negative ions were extracted.

The source gas to be supplied by the source gas supply unit 33 penetrates through the gas channel 43a formed inside the heater via the source gas supply line 31a to thereby be emitted from the surface of the heater 43. Further, the source gas emitted is supplied via the contact electrode 44 to the triple phase boundary of the negative ion source S, the contact electrode 44 and the source gas.

Further, the source gas supply unit 33 is configured to supply the source gas such that a total pressure of gases and a partial pressure of the source in a rear side of the contact electrode 44 are equal to or slightly higher than those in the extraction electrode 46 side of the negative ion source S. For example, in case where the total pressure is set at 1.1×10⁵ Pa and the partial pressure of the source is set at 1.1×10³ Pa by the nonreactive gas containing 1% source gas in the extraction electrode 46 side of the negative ion source S, the nonreactive gas containing 1% source gas is supplied such that the total pressure becomes 1.2×10⁵ Pa and the partial pressure of the source becomes 1.2×10³ Pa in the rear side of the contact electrode 44. By using such a partial pressure difference, a concentration gradient of a target ion in the negative ion source S is formed, so that the negative ions are easily extracted.

The gas exhaust unit 34 has a gas exhaust pump and the like, and is connected to the processing chamber 31 via the gas exhaust line 31c. The gas exhaust unit 34 discharges the gas from the processing chamber 31 to set an inner pressure of the processing chamber 31 at a pressure that will be discussed later.

The carrier gas supply unit 35 is connected to the processing chamber 31 through the carrier gas supply line 31b. The carrier gas supply unit 35 supplies the nonreactive gas such as argon, helium and nitrogen into the processing chamber 31 as the carrier gas transferring the negative ions extracted from the negative ion source S. At this time, the carrier gas supply unit 35 supplies into the processing chamber 31 the carrier gas with a relatively high gas velocity (e.g., 50 cm/s), so as to prevent the negative ions from colliding with the wall or recombining with other chemical species and thereby causing deactivation thereof.

The reduction unit 22 has a processing chamber 51 and a gas exhaust unit 52, and reduces the oxide film on the surface of the metallic film formed on the semiconductor wafer W by using the negative ions provided through the ion supply unit 21.

The processing chamber 51 is made of, e.g., aluminum, and connected to the processing chamber 31 of the ion supply unit 21 via the ion supply line 31d.

Inside the processing chamber 51, there are installed a table 51a for mounting thereon the semiconductor wafer W of the object to be processed; a heater 51b for heating the semiconductor wafer W mounted on the table 51a; a temperature gauge 51c for measuring a temperature of the table 51a (or the semiconductor wafer W mounted on the table 51a); and a pressure gauge 51d for measuring an inner pressure of the processing chamber 51.

Further, the temperature of the semiconductor wafer W to be heated by the heater 51b is set at a value appropriate for the reduction of the oxide film on the surface of the metallic film formed on the semiconductor wafer W by the negative ions.

The negative ions tend to be attracted to the metallic film rather than an insulating film of the electrical insulator (low-k film and the like). However, since the negative ions have high reactivity, if the temperature of the semiconductor wafer W is too high, the reaction between the insulating film and the negative ions may not be negligible. Further, if the temperature of the semiconductor wafer W is too high, the film quality of the low-k film or the like may be deteriorated. On the other hand, if the temperature of the semiconductor wafer W is too low, the reduction reaction may not be carried out sufficiently, even though the negative ions have high reactivity. Therefore, the temperature of the semiconductor wafer W to be heated by the heater 51b is set in the range from 30° C. to 200° C., preferably, from 100° C. to 180° C., and more preferably, 150° C.

By doing this, even though the negative ions are attached to the insulating film, the reaction between the insulating film and the negative ions may be neglected. Further, by an electrical repulsive force, it is prevented that the negative ions are excessively attached to the insulating layer over one layer coated on the insulating layer. Still further, by heating the semiconductor wafer W to the aforementioned temperature, it is possible to prevent the film quality of the low-k film or the like formed on the semiconductor wafer W from being deteriorated.

The gas exhaust unit 52 is connected to the processing chamber 51 via a gas exhaust line 54. The gas exhaust unit 52 has a gas exhaust pump and the like, and discharges the gas from the processing chamber 51 to set the inner pressure of the processing chamber 51 at a predetermined pressure (e.g., near atmospheric pressure).

As mentioned above, the negative ions tend to be attracted to the metallic film of a conductor rather than the insulating film of the electrical insulator (low-k film and the like). Thus, even though the inner pressure of the processing chamber 51 is maintained at an atmospheric pressure level, the negative ions reach the surface of the metallic film to thereby progress the reduction reaction.

The control unit 23 is formed of a microcomputer and the like, and stores a program for performing a reduction process for reducing a cuprous oxide film on the surface of the copper film, which is formed on the semiconductor wafer W. The control unit 23 controls entire operations of the reducing apparatus according to the program stored, to thereby reduce the cuprous oxide film on the surface of the copper film formed on the semiconductor wafer W.

For example, the control unit 23 controls the heater 43, and sets the temperature inside the processing chamber 31 at a predetermined temperature based on a measurement result from the temperature gauge 41. Further, the control unit 23 controls the gas exhaust unit 34, and sets the inner pressure of the processing chamber 31 at a predetermined pressure based on a measurement result from the pressure gauge 42. Still further, the control unit 23 controls the high voltage power supply 32, and applies an electric field to the negative ion source S with a predetermined intensity. Still further, the control unit 23 controls the carrier gas supply unit 35 to supply the carrier gas, and supplies the negative ions to the reduction unit 22. Still further, the control unit 23 controls the heater 51b, and heats the semiconductor wafer W to a predetermined temperature based on a measurement result from the temperature gauge 51c. Still further, the control unit 23 controls the gas exhaust unit 52, and sets the inner pressure of the processing chamber 51 at a predetermined temperature according to a measurement result from the pressure gauge 51d.

Next, a temperature of the negative ion source S heated through the heater 43, a voltage applied by the high voltage power supply 32 and an inner pressure of the processing chamber 31 set by the gas exhaust unit 34 will be discussed.

The negative ions in the negative ion source S are extracted by applying the electric field to the negative ion source S. At this time, if the temperature of the negative ion source S is too low, the negative ions in the negative ion source S are not activated and hard to be extracted. On the other hand, if the temperature of the negative ion source S is too high, activated negative ions are abnormally generated, so that the characteristic of the negative ion source S may be changed. Further, if the temperature of the negative ion source S is too high, a special ceramic or metal having a high heat resistance must be used for the heater 43, the electrode and the like installed inside the processing chamber 31.

Therefore, it is preferable that the temperature of the negative ion source S heated by the heater 43 is set at a temperature capable of extracting the negative ions from the negative ion source S and using a common metal, i.e., 250˜1000° C., preferably, 400˜800° C., and more preferably, 700° C.

By applying the electric field to the negative ion source S heated to the aforementioned preferred temperature, it is possible to extract the negative ions contained in the negative ion source S.

At this time, if the electric field applied is too low, the negative ions needed for the reduction cannot be obtained sufficiently. On the other hand, if the electric field applied is too high, the negative ions are excessively extracted more than as required.

In case where the negative ions are excessively extracted more than as required, the reactions between the negative ions and the parts (the inner wall of the processing chamber 31, the extraction electrode 46 and the like) other than a target part may affect the reduction process. Accordingly, the electric field intensity applied to the negative ion source S is set at a value capable of obtaining an amount of negative ions required (an amount of currents).

In case of reducing a 1 nm Cu₂O film formed on, e.g., a 200 mm semiconductor wafer W, hydride ions are needed with 2.7×10⁻⁶ mol. In case of reducing the Cu₂O film for a practical processing time (e.g., 1˜9 minutes), ions are needed with an amount corresponding to currents of 0.47 mA˜4.3 mA.

An amount of currents obtained from the negative ion source S becomes large as the size (the area of the surface where the ions are extracted) of the negative ion source S gets bigger and as the intensity of the electric field applied is heightened.

In case of using a hydrogen substituted C12A7 as the negative ion source S and heating the negative ion source S to 700° C., if the electric fields of 400 V/cm^{and} 1500 V/cm are applied, amounts of about 0.1 μA/cm² and 1.0 μA/cm² can be obtained, respectively.

Therefore, the intensity of the electric field applied to the negative ion source S (i.e., a voltage applied by the high voltage power supply 32) is set to obtain the aforementioned amount of currents (0.47˜4.3 mA) according to the size of the negative ion source S.

In the above-described reducing apparatus, since the processing chamber 51 of the reduction unit 22 is set at near atmospheric pressure, the pressure of the processing chamber 31 at the time of extracting the negative ions from the negative ion source S is set at a higher pressure than that of the processing chamber 51 under an oxygen reduced atmosphere by using the nonreactive gas or a source (hydrogen gas) containing nonreactive gas.

For example, the inner pressure of the negative ion generation chamber (processing chamber 31) is in the range from 0.9×10⁵ Pa to 1.1×10⁵ Pa by using 1% hydrogen containing Ar gas.

In such a pressure range, the electric field to be applied is in the range from 200 to 2000 V/cm where the discharge is not generated inside the negative ion generation chamber. At this time, an ionic current to be generated may be in the range from 0.05 to 1.4 μA/cm². More preferably, the electric field is in the range from 400 to 1500 V/cm, and the ionic current is between 0.1 and 1.0 μA/cm², at this time.

For example, the area of the negative ion source S, from which the ionic current can be obtained in the range from 0.47 to 4.3 mA to reduce the 1 nm Cu₂O film formed on the 200 mm semiconductor wafer W for the practical processing time, may be a value corresponding to the electrode of 4700˜10000 cm² from the preferred range of the electric field. Specifically, in case of a disk shape having 77 cm diameter (about 4700 cm² in area), if the electric field to be applied is in the range from 400 to 1500 V/cm, the ionic current of 0.47˜4.7 mA can be obtained.

Next, an operation of the reducing apparatus will be explained.

The negative ion source S is preset in the processing chamber (the negative ion generation chamber) 31, and the semiconductor wafer W is mounted on the table 51a through a transfer port (not shown) of the processing chamber (wafer processing chamber) 51.

If the semiconductor wafer W is mounted on the table 51a, operations of the ion supply unit 21 and the reduction unit 22 are controlled according to the program stored in advance to perform the following reduction process.

Specifically, the control unit 23 controls the source gas supply unit 33 to supply the source gas into the processing chamber 31, and at the same time, controls the gas exhaust unit 34 to set the inner pressure of the processing chamber 31 at a predetermined pressure (e.g., 1.1×10⁵ Pa (825 Torr)) according to a measurement result from the pressure gauge 42.

At this time, the control unit 23 is configured to supply the source gas such that the total pressure of gases and the partial pressure of the source gas in the rear side of the contact electrode 44 are higher than those in the extraction electrode 46 side of the negative ion source S (for example, the total pressure is 1.2×10⁵ Pa (the partial pressure of H₂ is 1.2×10³ Pa)) by using 1% H₂—Ar gas).

Further, the control unit 23 controls the heater 43 to heat the negative ion source S mounted on the contact electrode 44 to about 700° C., according to the measurement result of the temperature gauge 41.

Subsequently, the control unit 23 controls the carrier gas supply unit 35 to supply the carrier gas into the processing chamber 31 with a predetermined flow rate (e.g., 1% H₂—Ar of 500 sccm).

After that, the control unit 23 controls the high voltage power supply 32 to apply the voltage between the contact electrode 44 and the extraction electrode 46, to thereby apply the aforementioned intensity of electric field to the negative ion source S.

By doing this, the negative ions in the negative ion source S are extracted by the electric field applied. The negative ions extracted pass through the extraction electrode 46 to thereby be transferred to the reduction unit 22 by the carrier gas (the nonreactive gas) penetrating through the upper part inside the processing chamber 31.

Further, if the semiconductor wafer W is mounted on the table 51a, the control unit 23 controls the heater 51b to heat the semiconductor wafer W mounted on the table 51a to the predetermined temperature according to the measurement result from the temperature gauge 51c.

Subsequently, the control unit 23 controls the gas exhaust unit 52 to set the inner pressure of the processing chamber 51 at the near atmospheric pressure (e.g., 8×10⁴˜9×10⁴ Pa) according to the measurement result from the pressure gauge 51d.

Therefore, the negative ions supplied into the processing chamber 51 are mostly attached to the surface of the metallic film (the copper film) formed on the semiconductor wafer W to thereby react with the oxide film on the surface of the metallic film (the cuprous oxide film) Specifically, the oxide film on the surface of the metallic film is reduced by the reaction shown in the following reaction equation 1.
Cu₂O+2H⁻→2Cu+H₂O ↑ [reaction equation 1]

A reduced semiconductor wafer W is unloaded from the processing chamber 51 through the transfer port (not shown), and subsequently, an unprocessed semiconductor wafer W is mounted on the table 51a and is subject to the reduction process, as shown in the above.

As described above, by using the hydride ions (H⁻), it is possible to perform the reduction process at a low temperature at which the film quality of the low-k film can be maintained. Thus, the semiconductor apparatus can be manufactured with a high yield.

Further, since the negative ions tend to be attracted to the metallic film rather than the insulating film, the surface of the metallic film can be selectively processed without a special configuration, even in case of a high pressure of near atmospheric pressure.

Still further, since the reduction process is carried out at near atmospheric pressure, high performance exhaust pump and the like are not required for the gas exhaust unit 52 of the reduction unit 22, whereby cost for the apparatus can be reduced.

Still further, the negative ions can be obtained through a simple method of heating the negative ion source S and applying the electric field thereto. Accordingly, the ion supply unit 21 may have a simple configuration.

Still further, as described above, the reduction process using the negative ions can be carried out at near atmospheric pressure. Thus, the reducing apparatus may be mounted on or combined with other devices performing processes under the atmospheric pressure, without a complicated pressure control mechanism and the like. For example, the reduction unit may be mounted on or combined with a cleaning unit, a plating unit, a wafer prober, and the like, so that the above-described reduction process can be carried out before or after a cleaning processing, a plating processing, a probe processing, which is performed at the atmospheric pressure.

Still further, FIG. 3 illustrates a showerhead type injection opening as an injection opening for the negative ions in the processing chamber 51 of the reduction unit 21, but a nozzle type or the like may be used according to the size of the semiconductor wafer or the setting of the reduction apparatus.

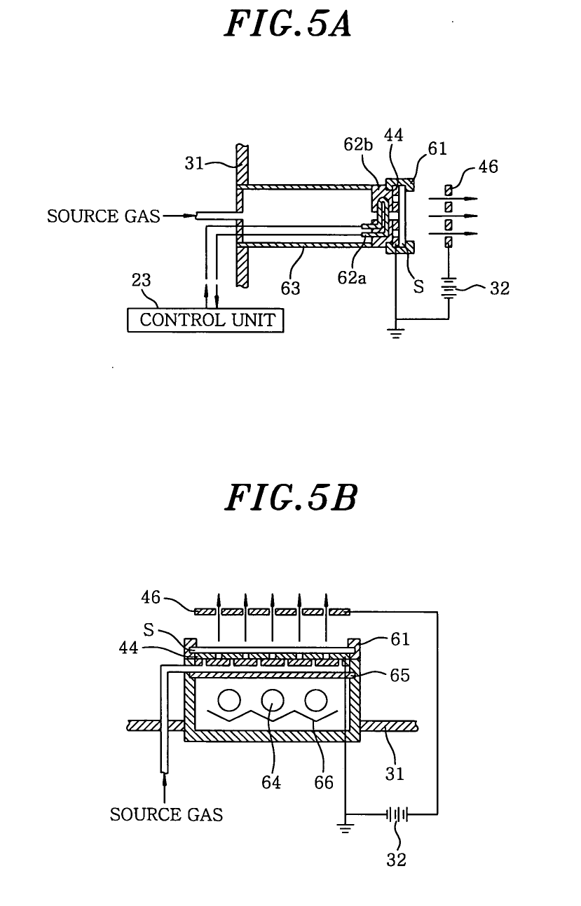

Still further, the configuration of the ion supply unit 21 is not confined to that of FIG. 3, and the configurations shown in FIGS. 5A through 5C may be adopted.

Specifically, in case of the disk shaped negative ion source S, as shown in FIG. 2A, the negative ion source S may be fixed by a clamp 61. In this case, the negative ion source S may be vertically installed, as described in FIG. 5A.

Further, as shown in FIG. 5A, a hole punched metallic hot plate 62b made of Ta or Mo and having therein an embedded heater 62a may be employed instead of the heater 43, and the hot plate 62b may be disposed on a hollow metallic tube 63 which buffers against a temperature change.

Still further, as shown in FIG. 5B, it can be configured such that multiple lamps 64 are installed and the negative ion source S is heated by radiant heats of the multiple lamps 64, instead of the heater 43. In this case, a quarts window 65 penetrating a light is installed between the contact electrode 44 and the lamps 64. Further, for focusing the radiant heats on the negative ion source S, a reflection plate 66 reflecting lights of the lamps 64 may be installed.

Still further, as shown in FIG. 5C, a microwave power supply 67 for generating a microwave, a waveguide 68a for propagating the microwave and a conic quarts glass (waveguide) 68b are installed, and the negative ion source S may be heated by the microwave. In this case, a uniform-heating plate 69 made of SiC, a mullite (3Al₂O₃.2SiO₂) and the like, having a high microwave absorptivity and a high thermal conductivity may be installed between the conic quartz glass 68b and the contact electrode 44, so as to uniformly apply heat over the entire surfaces of the negative ion source S.

Even though the ion supply unit 21 is formed as explained above, the negative ions are extracted from the negative ion source S, so that the surface of the metallic film formed on the semiconductor wafer W can be reduced, same as in the aforementioned embodiments.

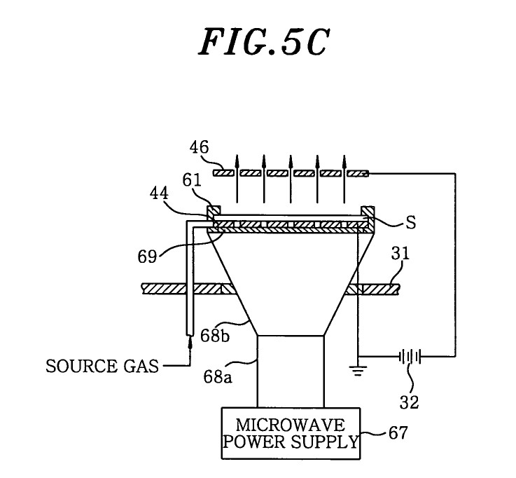

Further, as described in FIG. 6, the reducing apparatus can be configured such that an inside of one chamber is divided into a negative ion generation region (an ion generation chamber) 71 and a wafer processing region (a wafer processing chamber) 72. In this case, the extraction electrode 46 is disposed between the ion generation chamber 71 and the wafer processing chamber 72. The extraction electrode 46 serves as a conductance plate for adjusting a pressure difference between the ion generation chamber 71 and the wafer processing chamber 72, as well. Further, since the semiconductor wafer W is placed close to a high temperature negative ion source S, a susceptor 74 supporting the semiconductor wafer W may be a chilled plate instead of the hot plate, and the semiconductor wafer W may be maintained at 150° C.

Still further, two chambers may be combined into one, as shown in FIG. 6.

When configured as shown in FIG. 6, the transfer distance by the carrier gas is short, so that the deactivation of the hydride ion can be prevented.

Further, the reducing method of the surface of the metallic film may be applied for reducing surfaces of other metallic films as well as reducing the surface of the copper film. For example, it may be applied for reducing a surface of a metallic film such as aluminum or the like.

Still further, the ion supply unit 21 of FIG. 3 may be connected to a batch type processing chamber as well as a single wafer processing chamber. Namely, the reduction process mentioned above can be carried out on surfaces of metallic films formed on multiple substrates, inside the batch type processing chamber.

Still further, in the aforementioned embodiments, the hydrogen substituted C12A7 was described as an example of the negative ion source S containing the hydride ion, but other materials may be used as the negative ion source S providing the hydride ions.

As the negative ion source S providing the hydride ions, for instance, hydrogen substituted mayenite may be used.

While the invention has been shown and described with respect to the preferred embodiments, it will be understood by those skilled in the art that various changes and modifications may be made without departing from the spirit and scope of the invention as defined in the following claims.

1. A reducing apparatus for reducing an oxide film formed on a surface of a metallic film formed on a semiconductor wafer, wherein the oxide film is reduced by using hydride ions.

2. The reducing apparatus of claim 1, wherein the reducing apparatus comprises:
an ion generation unit for producing the hydride ions; and
an ion supply unit for supplying the hydride ions produced by the ion generation unit onto the semiconductor wafer.

3. The reducing apparatus of claim 2, wherein the ion generation unit includes:
a source heating unit for heating a negative ion source containing the hydride ions; and
an electric field applying unit for applying an electric field to the negative ion source heated by the source heating unit to extract the hydride ions contained in the negative ion source.

4. The reducing apparatus of claim 3, wherein the electric field applying unit applies to the negative ion source an electric field in the range from 200 to 2000 V/cm.

5. The reducing apparatus of claim 3, wherein the source heating unit heats the negative ion source to 250˜1000° C.

6. The reducing apparatus of any one of claims 1 through 5, wherein the reducing apparatus further comprises a wafer heating unit for heating the semiconductor wafer, and the wafer heating unit heats the semiconductor wafer to 30˜200° C.

7. The reducing apparatus of any one of claims 1 through 5, wherein the reducing apparatus further comprises:
a processing chamber for performing a reduction process on the oxide film; and
a pressure control unit for controlling an inner pressure of the processing chamber,
wherein the inner pressure of the processing chamber is set at a near atmospheric pressure by the pressure control unit.

8. The reducing apparatus of any one of claims 1 through 5, wherein the metallic film is formed of a copper, and the oxide film is formed of cuprous oxide.

9. A method for reducing an oxide film formed on a surface of a metallic film formed on a semiconductor wafer, wherein the oxide film being reduced by using hydride ions.
